(19) United States
(12) Patent Application Publication
(10) Pub. No.: US 2025/0351706 A1
(43) Pub. Date: Nov. 13, 2025

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventors: KYOUNGSUB SO, Yongin-si (KR); HYOUNGJOO LEE, Yongin-si (KR); KYOUNGWOO PARK, Yongin-si (KR)

(21) Appl. No.: 19/017,362

(22) Filed: Jan. 10, 2025

(30) Foreign Application Priority Data
May 10, 2024 (KR) 10-2024-0061707

(51) Int. Cl. H10K 59/80; H10K 59/12

(52) U.S. Cl. CPC H10K 59/873; H10K 59/1201

(57) ABSTRACT

A display device includes a display panel including a first area, a second area adjacent to the first area and bent with respect to a bending axis extending in one direction, and a third area adjacent to the second area and including an alignment mark, a cover layer below the third area of the display panel and covering the alignment mark, and a cover panel between the first area and the third area of the display panel and in contact with the display panel.

### CROSS-REFERENCE TO RELATED APPLICATION

The present application claims priority to and the benefit of Korean Patent Application No. 10-2024-0061707, filed on May 10, 2024, in the Korean Intellectual Property Office, the entire disclosure of which is incorporated herein by reference.

### BACKGROUND

### 1. Field

Embodiments of the present disclosure relate to a display device. For example, embodiments of the present disclosure relate to a display device that provides visual information and a method of manufacturing the display device.

### 2. Description of the Related Art

A display device may include a display panel including a plurality of pixels that display an image, and a driver that drives these pixels. The pixels may be arranged in a display area of the display panel, while the driver may be arranged in a non-display area of the display panel around (e.g., surrounding) the display area. The display panel may define a bending area between the driver and the display area, allowing the bending area to be bent so that the driver is arranged below the display area.

During a process of manufacturing the display panel, an alignment mark may be defined in the non-display area of the display panel. This alignment mark may be utilized to align the display panel and other members, or to align the bending of the display panel.

The above information disclosed in this Background section is intended to enhance understanding of the background of the disclosure and may contain information that does not constitute prior art.

### SUMMARY

Aspects of one or more embodiments of the present disclosure relate to a display device with an improved recognition rate of an alignment mark.

Aspects of one or more embodiments of the present disclosure relate to a method of manufacturing the display device.

Aspects of one or more embodiments of the present disclosure relate to an electronic device including the display device.

Additional aspects will be set forth in part in the description which follows and, in part, will be apparent from the description, or may be learned by practice of the presented embodiments of the disclosure.

A display device according to one or more embodiments of the present disclosure includes a display panel including a first area, a second area adjacent to the first area and bent with respect to a bending axis extending in one direction, and a third area adjacent to the second area and including an alignment mark, a cover layer arranged below the third area of the display panel and covering the alignment mark, and a cover panel arranged between the first area and the third area of the display panel and in contact with the display panel.

In one or more embodiments, a first width of the third area of the display panel in the one direction may be equal to a second width of the cover layer in the one direction.

In one or more embodiments, in a plan view, first side surfaces at opposite ends of the third area of the display panel in the one direction may overlap second side surfaces at opposite ends of the cover layer in the one direction, respectively.

In one or more embodiments, the cover panel may include a first surface in contact with the first area of the display panel, and a second surface in contact with the third area of the display panel.

In one or more embodiments, the third area of the display panel may be arranged below the first area of the display panel.

In one or more embodiments, the cover layer may include a first cover layer including an optically transparent material, and a second cover layer arranged on the first cover layer and including a conductive material.

In one or more embodiments, the first cover layer may overlap the alignment mark in the plan view, and the second cover layer may not overlap the alignment mark in the plan view.

In one or more embodiments, a third width of the first cover layer in the one direction may be greater than a fourth width of the second cover layer in the one direction.

In one or more embodiments, the third width of the first cover layer may be equal to the first width of the third area of the display panel.

In one or more embodiments, in the plan view, third side surfaces at opposite ends of the first cover layer in the one direction may not overlap fourth side surfaces at opposite ends of the second cover layer in the one direction, respectively.

In one or more embodiments, in the plan view, the third side surfaces of the first cover layer may overlap the first side surfaces of the display panel, respectively.

In one or more embodiments, the display device may further include a circuit board coupled to the third area of the display panel, and the cover layer may cover at least a portion of the circuit board.

In one or more embodiments, the circuit board may include a conductive pattern overlapping the cover layer in the plan view, and the first cover layer may define an opening overlapping the conductive pattern in the plan view.

In one or more embodiments, the display panel may include a data driver arranged in the third area, and the cover layer may cover the data driver.

In one or more embodiments, the first cover layer may include a first transmission layer and a second transmission layer arranged on the first transmission layer, and the first transmission layer may define an opening overlapping the data driver in the plan view.

A method of manufacturing a display device according to one or more embodiments of the present disclosure includes: providing (e.g., supplying) a preliminary display panel including a first area, a second area adjacent to the first area and being bendable, a third area adjacent to the second area and including an alignment mark, and a dummy area defining the first area, the second area, and the third area, forming a preliminary cover layer covering the alignment mark in the third area and the dummy area on the preliminary display panel, cutting the preliminary display panel and the preliminary cover layer along the dummy area (e.g., along a boundary defining the dummy area) to form a display panel including the first area, the second area, and the third area and a cover layer covering the alignment mark, and coupling a cover panel to a lower portion of the display panel.

In one or more embodiments, a first width of the third area of the display panel in one direction may be equal to a second width of the cover layer in the one direction.

In one or more embodiments, in a plan view, first side surfaces at opposite ends of the third area of the display panel in the one direction may overlap second side surfaces at opposite ends of the cover layer in the one direction, respectively.

In one or more embodiments, the method may further include bending the second area of the display panel with respect to a bending axis extending in one direction to position the third area of the display panel below the first area of the display panel.

In one or more embodiments, a first surface of the cover panel may be in contact with the first area of the display panel, and a second surface of the cover panel may be in contact with the third area of the display panel.

In one or more embodiments, the forming of the preliminary cover layer may include forming a first cover layer overlapping the alignment mark in the plan view, and forming a second cover layer on the first cover layer, the second layer not overlapping the alignment mark in the plan view.

In one or more embodiments, after the cutting the preliminary display panel and the preliminary cover layer, a third width of the first cover layer in the one direction may be equal to the first width of the third area of the display panel.

In one or more embodiments, after the cutting the preliminary display panel and the preliminary cover layer, in the plan view, third side surfaces at opposite ends of the first cover layer in the one direction may overlap the first side surfaces of the display panel, respectively.

In one or more embodiments, the method may further include coupling the third area and a circuit board, the circuit board may include a conductive pattern overlapping the cover layer in a plan view, and the cover layer may define an opening overlapping the conductive pattern in the plan view.

In one or more embodiments, the display panel may include a data driver arranged in the third area, the cover layer may cover the data driver, and the cover layer may define an opening overlapping the data driver in a plan view.

According to one or more embodiments of the present disclosure, an electronic device includes a display device including a display panel comprising a first area, a second area adjacent to the first area and bent with respect to a bending axis extending in one direction, and a third area adjacent to the second area and comprising an alignment mark; a cover layer below the third area of the display panel and covering the alignment mark; and a cover panel between the first area and the third area of the display panel and in contact with the display panel.

In one or more embodiments, the electronic device may be a portable communication device, a medical display device, a vehicle, a ship or an aircraft.

In a display device according to one or more embodiments of the present disclosure, the display device may include a display panel including a first area in which a display area is defined, a second area defined as a bending area, and a third area arranged below the first area and in which an alignment mark is defined, a cover panel in contact with the display panel, and a cover layer extending to cover the alignment mark on the third area. Because an area in which the alignment mark is defined may be supported by the cover layer to supplement rigidity, even if a separate component (e.g., a protective film) is not arranged between the display panel and the cover panel, a recognition rate of the alignment mark may be improved when confirming alignment of the alignment mark after bending the second area. Accordingly, the display device may be thinned, and process costs may be reduced.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is an exploded perspective view schematically illustrating a display device according to one or more embodiments of the present disclosure.

FIG. 2 is a rear view illustrating the display device of FIG. 1, according to one or more embodiments of the present disclosure.

FIG. 3 is a cross-sectional view taken along the line I-I′ of FIG. 2, according to one or more embodiments of the present disclosure.

FIG. 4 is a cross-sectional view taken along the line II-II′ of FIG. 2, according to one or more embodiments of the present disclosure.

FIG. 5 is a plan view illustrating a display panel, a bending protection layer, a cover layer, and a circuit board included in the display device of FIG. 1, according to one or more embodiments of the present disclosure.

FIG. 6 is a cross-sectional view taken along the line III-III′ of FIG. 5, according to one or more embodiments of the present disclosure.

FIG. 7 is a cross-sectional view taken along the line IV-IV′ of FIG. 5, according to one or more embodiments of the present disclosure.

FIG. 8 is a plan view illustrating a display device according to one or more embodiments of the present disclosure.

FIG. 9 is an enlarged plan view of area A of FIG. 8, according to one or more embodiments of the present disclosure.

FIG. 10 is a cross-sectional view taken along the line V-V′ of FIG. 9, according to one or more embodiments of the present disclosure.

FIG. 11 is a plan view illustrating a display device according to one or more embodiments of the present disclosure.

FIG. 12 is an enlarged plan view of area B of FIG. 11, according to one or more embodiments of the present disclosure.

FIG. 13 is a cross-sectional view taken along the line VI-VI′ of FIG. 12, according to one or more embodiments of the present disclosure.

FIGS. 14, 15, and 16 are views illustrating a method of manufacturing a display device according to one or more embodiments of the present disclosure.

FIG. 17 is a block diagram illustrating an electronic device according to one or more embodiments of the present disclosure.

FIG. 18 is a schematic view illustrating electronic devices according to embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, embodiments of the present disclosure will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion.

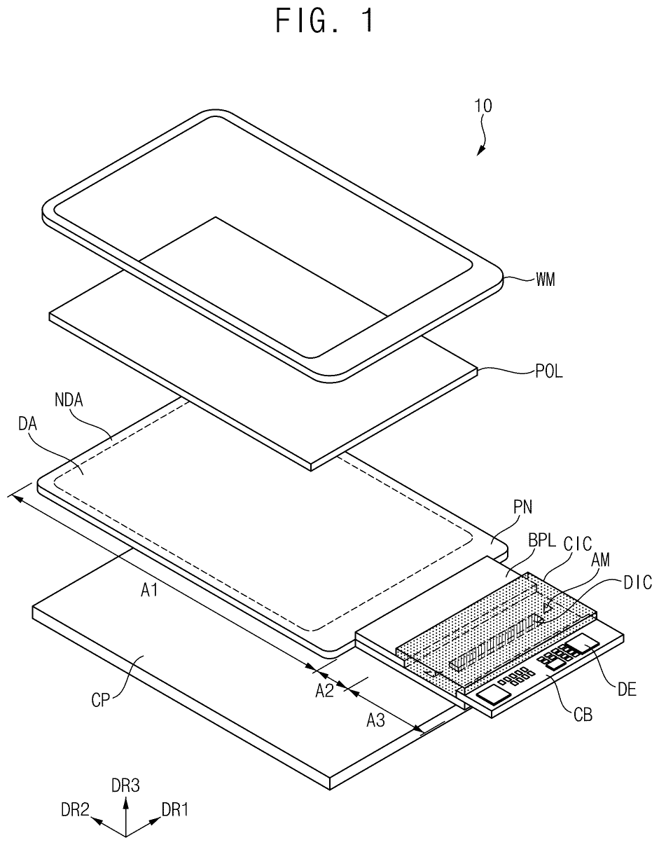

FIG. 1 is an exploded perspective view schematically illustrating a display device according to one or more embodiments of the present disclosure. For example, FIG. 1 may be an exploded perspective view illustrating a state before the display panel PN is bent.

Referring to FIG. 1, a display device 10 may display an image on a display surface parallel to a plane defined by a first direction DR1 and a second direction DR2 intersecting the first direction DR1 (e.g., a plan view). For example, the display device 10 may display an image in a third direction DR3 intersecting each of the first direction DR1 and the second direction DR2. For example, the display surface may correspond to a front surface of the display device 10. For example, the first direction DR1, the second direction DR2, and the third direction DR3 may be normal (e.g., perpendicular) to each other. In the present specification, the term “in a plan view” may refer to a case when viewed from the third direction DR3.

The display device 10 may include a window WM, a polarizing layer POL, a display panel PN, a bending protection layer BPL, a circuit board CB, a cover layer CIC, and a cover panel CP.

The window WM may include an optically transparent material. For example, the window WM may include glass, plastic, sapphire, and/or the like. The window WM may include a material having a relatively high transmittance, and may be to transmit light generated from the display panel PN. The window WM may protect the display panel PN from external impact.

The window WM may have a single-layer structure or a multi-layer structure. For example, the window WM may include a plurality of plastic films bonded with an adhesive, or may include a glass substrate and a plastic film bonded with an adhesive. The window WM may further include a functional coating layer. For example, the functional coating layer may include an anti-fingerprint layer, an anti-reflection layer, a hard coating layer, and/or the like.

The polarizing layer POL may be arranged below the window WM. The polarizing layer POL may reduce reflectance of external light incident on the window WM. For example, the polarizing layer POL may prevent or reduce external light incident through the front surface of the display device 10 from being reflected by components included in the display panel PN and being visually recognized from the outside.

For example, the polarizing layer POL may include a phase retarder or a polarizer. The phase retarder may be a film type (kind) or a liquid crystal coating type (kind), and may include a λ/2 phase retarder or a λ/4 phase retarder. The polarizer may also be a film type (kind) or a liquid crystal coating type (kind). For example, the phase retarder and the polarizer may be a single polarizing film. The polarizing layer POL may further include a protective film arranged on or below the polarizing film.

The display panel PN may be arranged below the polarizing layer POL. The display panel PN may include a display area DA and a non-display area NDA. The display area DA may be an area that displays an image, and the non-display area NDA may be an area that does not display an image.

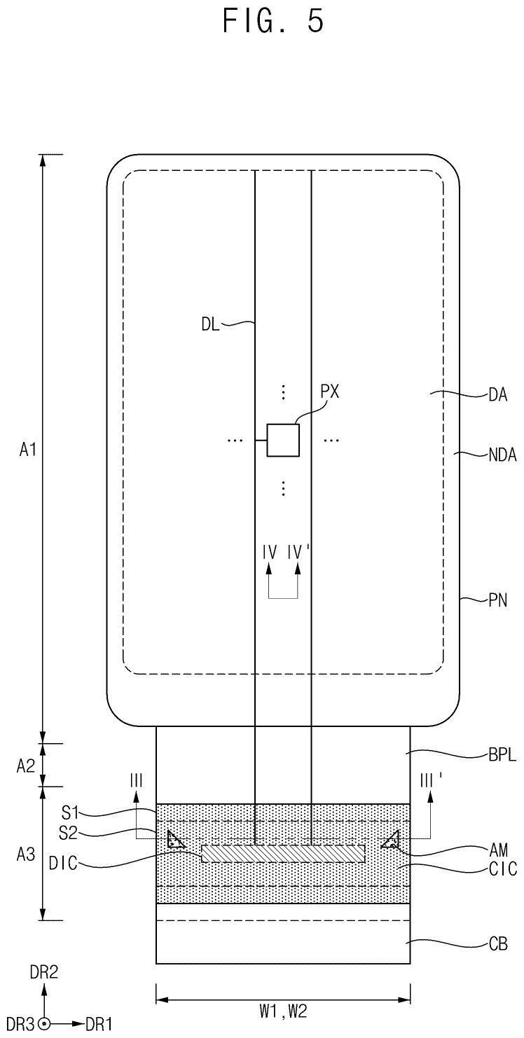

Pixels (e.g., pixels PX as shown, e.g., in FIG. 5) that display light may be arranged in the display area DA. The non-display area NDA may be arranged around the display area DA. For example, the non-display area NDA may be around (e.g., surround) the display area DA in a plan view. A driver for displaying an image in the display area DA may be arranged in the non-display area NDA. The display area DA and the non-display area NDA may correspond to a display area that displays an image and a non-display area that does not display an image of the display device 10, respectively.

The display panel PN may include a first area A1, a second area A2, and a third area A3. The second area A2 may be adjacent to the first area A1, and the third area A3 may be adjacent to the second area A2. In one or more embodiments, the second area A2 may be arranged between the first area A1 and the third area A3. For example, the first area A1, the second area A2, and the third area A3 may be arranged in a direction opposite to the second direction DR2. The first, second, and third areas A1, A2, and A3 may extend in the direction opposite to the second direction DR2.

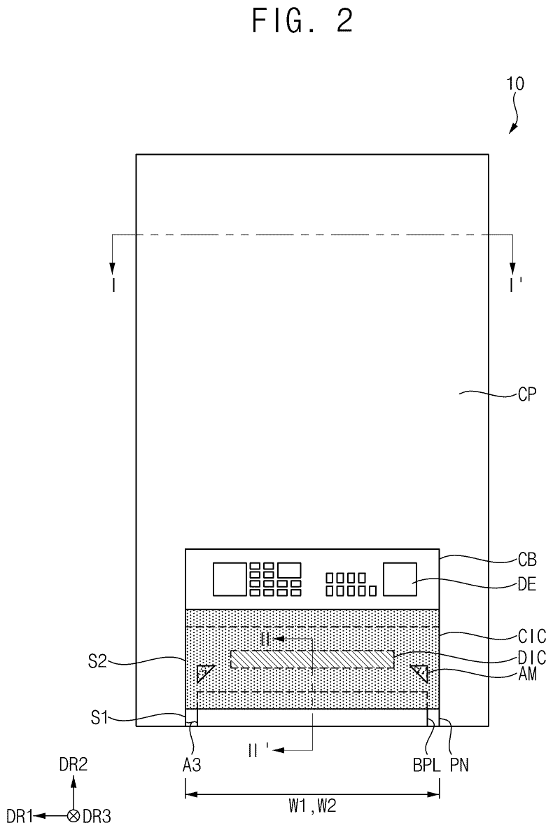

A portion of the first area A1 may be included in the display area DA, and the other portion of the first area A1, the second area A2, and the third area A3 may be included in the non-display area NDA. For example, the first area A1 may define (include) the display area DA. In one or more embodiments, the second area A2 may be a bending area that is bent with respect to a bending axis (see, e.g., FIGS. 2 and 4), and each of the first area A1 and the third area A3 may be a non-bending area that is not bent.

The display panel PN may include a data driver DIC and an alignment mark AM. The data driver DIC may be mounted in the third area A3 on the display panel PN. The data driver DIC may include a data driving circuit that drives the pixels of the display panel PN. The alignment mark AM may be defined in the third area A3 of the display panel PN. For example, the alignment mark AM may be arranged adjacent to side surfaces of the third area A3, facing away from each other along the first direction DR1. In other words, in the third area A3, the alignment mark AM may be adjacent to side surfaces of the display panel PN, where the side surfaces (facing away from each other) are at opposite ends of the third area A3 of the display panel PN in the first direction DR1.

The bending protection layer BPL may be arranged in the second area A2 on the display panel PN. The bending protection layer BPL may be further arranged in a portion of the first area A1 and a portion of the third area A3 on the display panel PN. The bending protection layer BPL may be bent together with the second area A2 of the display panel PN. The bending protection layer BPL may protect the second area A2 of the display panel PN from external impact, and may control bending stress of the second area A2.

The circuit board CB may be arranged in a portion of the third area A3 on the display panel PN. The circuit board CB may be coupled to one end of the display panel PN through a bonding process. The circuit board CB may be coupled to an end of the third area A3. The circuit board CB may be electrically connected to the display panel PN. For example, the circuit board CB may be electrically connected to the display panel PN through an anisotropic conductive adhesive layer. The circuit board CB may include a driving element DE mounted on the circuit board CB. The driving element DE may convert a signal input from the outside into a signal for the data driver DIC or into a signal for driving the display panel PN.

The cover layer CIC may be arranged in the third area A3 on the display panel PN. In one or more embodiments, the cover layer CIC may cover the data driver DIC and the alignment mark AM. The cover layer CIC may further cover a portion of the bending protection layer BPL and a portion of the circuit board CB. The cover layer CIC may block noise that may be formed near the data driver DIC and the circuit board CB, and may protect the data driver DIC and the circuit board CB from external impact.

The cover panel CP may be arranged below the display panel PN. The cover panel CP may improve impact resistance of the display device 10. The cover panel CP may include one or more suitable functional layers such as an impact absorbing layer that absorbs external impact, a supporting layer that supports the display panel PN, a heat dissipating layer that dissipates heat generated by the display panel PN, and/or the like. For example, the cover panel CP may include a metal, a cushion member, and/or the like.

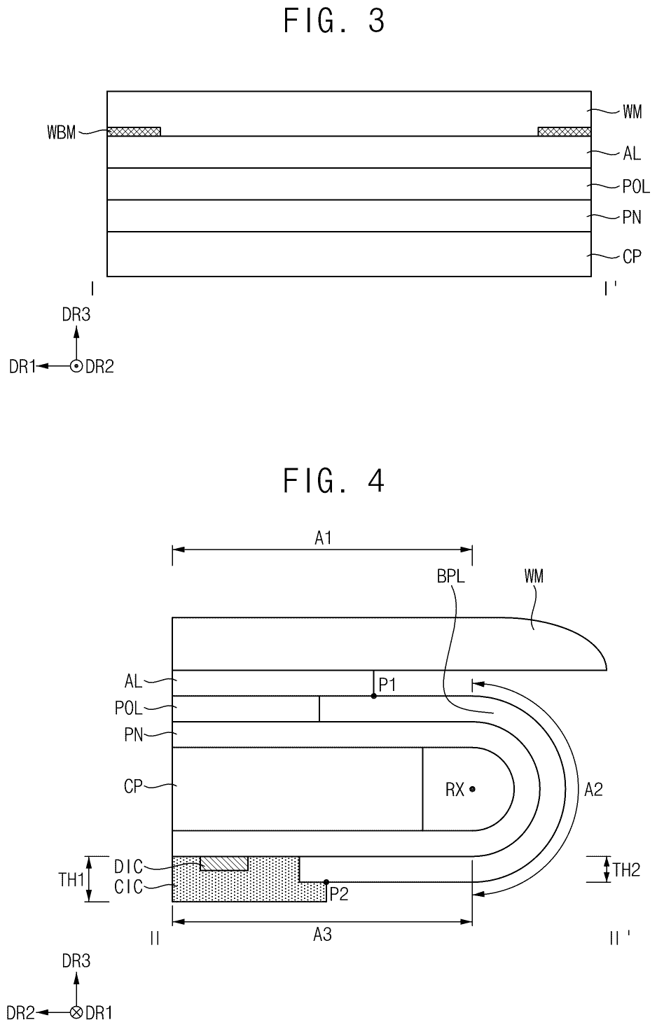

FIG. 2 is a rear view illustrating the display device of FIG. 1, according to one or more embodiments of the present disclosure. FIG. 3 is a cross-sectional view taken along the line I-I′ of FIG. 2, according to one or more embodiments of the present disclosure. FIG. 4 is a cross-sectional view taken along the line II-II′ of FIG. 2, according to one or more embodiments of the present disclosure.

For example, FIG. 2 may be a rear view illustrating a state after the display panel PN is bent, FIG. 3 may be a cross-sectional view taken from the first area A1, and FIG. 4 may be a cross-sectional view taken from the first, second, and third areas A1, A2, and A3.

Referring to FIGS. 1, 2, 3, and 4, the display device 10 may include the window WM, an adhesive layer AL, the polarizing layer POL, the display panel PN, the cover panel CP, the bending protection layer BPL, and the cover layer CIC.

The window WM may include a window light-blocking pattern WBM. The window light-blocking pattern WBM may be arranged on a lower surface of the window WM (i.e., a surface adjacent to the display panel PN of the window WM). The window light-blocking pattern WBM may overlap the non-display area NDA in a plan view. The window light-blocking pattern WBM may include a light-blocking material. For example, the window light-blocking pattern WBM may include an organic material having a black color. The window light-blocking pattern WBM may cover the non-display area NDA so as not to be visually recognized from the outside.

The adhesive layer AL may be arranged between the window WM and the polarizing layer POL, and may couple the window WM and the polarizing layer POL. The adhesive layer AL may be optically transparent. For example, the adhesive layer AL may include a pressure sensitive adhesive (PSA), an optically clear adhesive (OCA), an optically clear resin (OCR), and/or the like.

The display panel PN and the cover panel CP may be arranged below the polarizing layer POL. The polarizing layer POL may be arranged in the first area A1 on the display panel PN, and the cover panel CP may be arranged between the first area A1 and the third area A3 of the display panel PN, e.g., when the display panel PN is bent. The display panel PN may include the first and third areas A1 and A3 that are not bent and the second area A2 that is bent.

The second area A2 of the display panel PN may be bent with respect to a bending axis RX. The bending axis RX may extend in the first direction DR1. The second area A2 may be bent in a direction toward a lower surface of the display panel PN (i.e., a surface spaced and/or apart (e.g., spaced apart or separated) from the window WM of the display panel PN). For example, the second area A2 may be bent in a direction opposite to the third direction DR3.

Accordingly, the first area A1 of the display panel PN may be arranged on an upper surface of the cover panel CP (i.e., a surface adjacent to the window WM of the cover panel CP), and the third area A3 of the display panel PN may be arranged below a lower surface of the cover panel CP (i.e., a surface spaced and/or apart (e.g., spaced apart or separated) from the window WM of the cover panel CP). The upper surface and the lower surface of the cover panel CP may be opposite to (e.g., may face away from) each other. The third area A3 may be arranged below the first area A1, and the first area A1 and the third area A3 may be opposite to (e.g., may face away from) each other in the third direction DR3.

In one or more embodiments, the display device 10 may not include (e.g., may exclude) a separate component arranged between the cover panel CP and the display panel PN. For example, the display device 10 may not include (e.g., may exclude) a separate protective film arranged between the cover panel CP and the display panel PN to protect the display panel PN. For example, the protective film may include a flexible plastic material such as polyethylene terephthalate and/or the like, and may protect the first and third areas A1 and A3 of the display panel PN.

Accordingly, in one or more embodiments, the cover panel CP may be in direct contact with the display panel PN. The cover panel CP may include first and second adhesive layers that couple the display panel PN and the cover panel CP. The upper surface of the cover panel CP may be directly coupled (or in direct contact with) the first area A1 of the display panel PN through the first adhesive layer, and the lower surface of the cover panel CP may be directly coupled (or in direct contact with) the third area A3 of the display panel PN through the second adhesive layer.

The display panel PN may include the data driver DIC and the alignment mark AM arranged in the third area A3, and the circuit board CB may be arranged in the third area A3 on the display panel PN. The data driver DIC, the alignment mark AM, and the circuit board CB may be arranged below the lower surface of the cover panel CP.

In one or more embodiments, the alignment mark AM may be a mark for confirming bending of the display panel PN. For example, the alignment mark AM may be a mark for confirming whether the display panel PN is bent and aligned so that the second area A2 has an appropriate or suitable curvature. For example, by capturing an image of the alignment mark AM in the third direction DR3 below the cover panel CP, the bending of the display panel PN may be confirmed.

Although FIGS. 1 and 2 illustrate that the display panel PN includes two alignment marks AM arranged adjacent to both side surfaces S1, where the side surfaces S1 are at opposite ends of the third area A3 of the display panel PN, facing away from each other along the first direction DR1, the present disclosure is not limited thereto. For example, the display panel PN may include one or more alignment marks AM, and the position of the alignment mark(s) AM may be variously changed.

In addition, although FIGS. 1 and 2 illustrate that the alignment mark AM has a triangular planar shape, the present disclosure is not limited thereto. For example, the alignment mark AM may have one or more suitable shapes such as a planar shape of a cross, an L-shaped planar shape, and/or the like.

The bending protection layer BPL may be arranged in the second area A2 on the display panel PN, and may be bent together with the display panel PN. The bending protection layer BPL may extend to the first and third areas A1 and A3 on the display panel PN. The bending protection layer BPL may extend from the second area A2 of the display panel PN, such that a portion of the bending protection layer BPL may be arranged between the first area A1 of the display panel PN and the adhesive layer AL, and a portion of the bending protection layer BPL may be arranged between the third area A3 of the display panel PN and the cover layer CIC.

The cover layer CIC may be arranged in the third area A3 on the display panel PN, and may be arranged below the cover panel CP. The cover layer CIC may cover the data driver DIC and the alignment mark AM of the display panel PN. The cover layer CIC may cover a portion of the bending protection layer BPL and a portion of the circuit board CB, and may not cover the driving element DE of the circuit board CB. For example, the cover layer CIC may be fixed to the display panel PN, the bending protection layer BPL, and the circuit board CB by an adhesive method.

In one or more embodiments, because the cover layer CIC covers the alignment mark AM, even if a separate component (e.g., a protective film) is not arranged between the display panel PN and the cover panel CP, a rigidity of an area in which the alignment mark AM is defined may be supplemented by the cover layer CIC. Accordingly, even if (e.g., when) an alignment of the alignment mark AM is confirmed, a recognition rate of the alignment mark AM may not be reduced.

In one or more embodiments, a first width W1 of the third area A3 of the display panel PN may be substantially equal to a second width W2 of the cover layer CIC. Here, the first width W1 may be a length in the first direction DR1 of the third area A3 of the display panel PN, and the second width W2 may be a length in the first direction DR1 of the cover layer CIC. In a plan view, first side surfaces S1 at opposite ends of the third area A3 of the display panel PN, facing away from each other along the first direction DR1 and second side surfaces S2 at opposite ends of the cover layer CIC, facing away from each other along the first direction DR1 may overlap (e.g., may align), respectively. In other words, in the third area A3 of the display panel PN, the display panel PN may have first side surfaces S1, one of the first side surfaces S1 is at an end (a first end) of the upper surface of the display panel PN along the first direction DR1, and the other first side surface is at another end, opposite to the first end, of the upper surface of the display panel PN along the first direction DR1. The length of the first side surfaces S1 may extend in the second direction DR2. The cover layer CIC may have second side surfaces S2 adjacent the first side surfaces S1. Similar to the first side surfaces S1, the second side surfaces S2 are at opposite ends of an upper surface of the cover layer CIC along the first direction DR1. The second side surfaces S2 may also extend in the second direction DR2, and each of the second side surfaces may be aligned with a respective one of the first side surfaces S1.

When the second area A2 of the display panel PN is bent, bending stress may occur at each of a first point P1 on the first area A1 and a second point P2 on the third area A3, and a curvature may be formed at a point where the maximum bending stress occurs in the second area A2. In such embodiments, if (e.g., when) the point where the maximum bending stress occurs is close to a center area between the first point P1 and the second point P2, an appropriate or suitable curvature may be formed to prevent or reduce the likelihood of a driving failure of the display device 10.

In one or more embodiments, because the cover panel CP and the display panel PN may be in direct contact with each other, the first point P1 may be adjacent to a point where the bending protective layer BPL and the adhesive layer AL are in contact, and the second point P2 may be adjacent to a point where the bending protective layer BPL and the cover layer CIC are in contact. In order to form an appropriate or suitable curvature in the second area A2, a first thickness TH1 of the cover layer CIC and a second thickness TH2 of the bending protective layer BPL may be adjusted. Here, the first thickness TH1 may be a length of the cover layer CIC in the third direction DR3, and the second thickness TH2 may be a length of the bending protective layer BPL in the third direction DR3. For example, the point where the maximum bending stress occurs may be controlled or selected by adjusting the first thickness TH1 and the second thickness TH2.

For example, if the first thickness TH1 is relatively thin and the second thickness TH2 is relatively thick, the point where the maximum bending stress occurs may be relatively close to the first point P1, so that an appropriate or suitable curvature may not be formed and a driving failure of the display device 10 may occur.

Accordingly, in one or more embodiments, the first thickness TH1 may be adjusted to be proportional to the second thickness TH2. For example, if (e.g., when) the second thickness TH2 is relatively thick, the first thickness TH1 may also be relatively thick, and if (e.g., when) the second thickness TH2 is relatively thin, the first thickness TH1 may also be relatively thin. However, in the present disclosure, the first thickness TH1 is not limited, and the first thickness TH1 may be variously changed in consideration of the second thickness TH2, a material included in the cover layer CIC, physical properties (e.g., modulus) of the material, and/or the like.

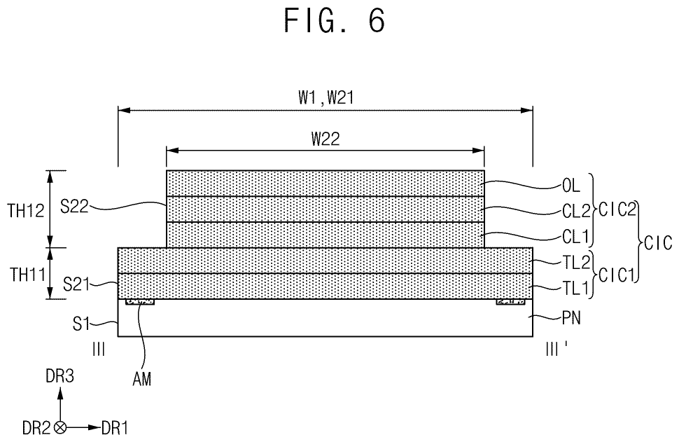

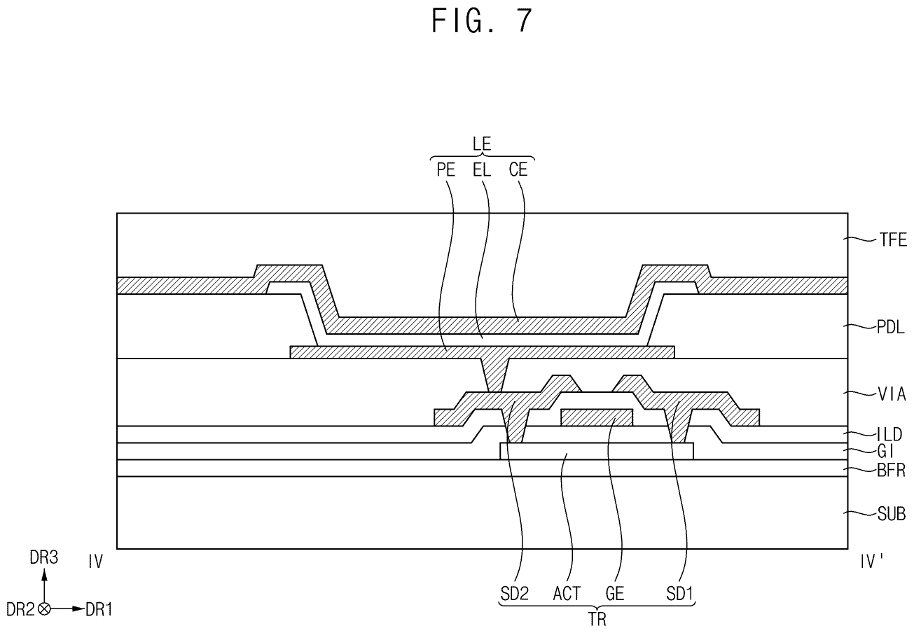

FIG. 5 is a plan view illustrating a display panel, a bending protection layer, a cover layer, and a circuit board included in the display device of FIG. 1, according to one or more embodiments of the present disclosure. FIG. 6 is a cross-sectional view taken along the line III-III′ of FIG. 5, according to one or more embodiments of the present disclosure. FIG. 7 is a cross-sectional view taken along the line IV-IV′ of FIG. 5, according to one or more embodiments of the present disclosure.

For example, FIG. 5 may be a plan view illustrating a state before the display panel PN is bent, FIG. 6 may be a cross-sectional view taken from the third area A3, and FIG. 7 may be a cross-sectional view taken from the display area DA.

Referring to FIGS. 1, 4, 5, 6, and 7, the display device 10 may include the display panel PN and the cover layer CIC.

The display panel PN may include the display area DA and the non-display area NDA. Pixels PX arranged along the first direction DR1 and the second direction DR2 may be arranged in the display area DA. As each of the pixels PX may be to emit light, the display area DA may display an image. Lines connected to the pixels PX may be further arranged in the display area DA. For example, the lines may include a data line DL, a gate signal line, a power line, and/or the like. The lines may extend in the first direction DR1 or the second direction DR2.

Drivers that drive the pixels PX may be arranged in the non-display area NDA. For example, the drivers may include the data driver DIC, a gate driver, a power voltage generator, a timing controller, and/or the like. The pixels PX may be to emit light based on signals received from the drivers.

The display panel PN may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE. The transistor TR may include an active pattern ACT, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, the substrate SUB may include plastic, glass, quartz, silicon, and/or the like. These may be used alone or in combination with each other.

The buffer layer BFR may be arranged on the substrate SUB. The buffer layer BFR may prevent or reduce the likelihood of metal atoms, impurities, and/or the like from diffusing into the transistor TR. In addition, the buffer layer BFR may improve the flatness of a surface of the substrate SUB if (e.g., when) the surface of the substrate SUB is not substantially uniform. The buffer layer BFR may include an inorganic material such as silicon oxide (SiOₓ, where 0<x≤2), silicon nitride (SiₓN_{y}, where 0<x≤3 and 0<y≤4, e.g., Si₃N₄), silicon oxynitride (SiOₓN_{y}, where, e.g., 0<x≤2 and 0<y≤2), and/or the like. These may be used alone or in combination with each other.

The active pattern ACT may be arranged on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, and/or the like. Examples of the oxide semiconductor material may include indium gallium zinc oxide (IGZO), indium tin zinc oxide (ITZO), and/or the like. These may be used alone or in combination with each other.

The gate insulating layer GI may be arranged on the active pattern ACT, and may cover the active pattern ACT. The gate insulating layer GI may include an inorganic material such as silicon oxide, silicon nitride, silicon oxynitride, and/or the like. These may be used alone or in combination with each other.

The gate electrode GE may be arranged on the gate insulating layer GI. The gate electrode GE may overlap the channel area of the active pattern ACT in a plan view. The gate electrode GE may include a metal, an alloy, a conductive metal nitride, a conductive metal oxide, a transparent conductive material, and/or the like. These may be used alone or in combination with each other.

The interlayer insulating layer ILD may be arranged on the gate electrode GE, and may cover the gate electrode GE. The interlayer insulating layer ILD may include an inorganic material such as silicon oxide, silicon nitride, silicon oxynitride, and/or the like. These may be used alone or in combination with each other.

The first electrode SD1 and the second electrode SD2 may be arranged on the interlayer insulating layer ILD. The first electrode SD1 may be connected to the source area of the active pattern ACT through a first contact hole penetrating (e.g., passing through) the gate insulating layer GI and the interlayer insulating layer ILD. In addition, the second electrode SD2 may be connected to the drain area of the active pattern ACT through a second contact hole penetrating (e.g., passing through) the gate insulating layer GI and the interlayer insulating layer ILD. For example, each of the first electrode SD1 and the second electrode SD2 may include a metal, an alloy, a conductive metal nitride, a conductive metal oxide, a transparent conductive material, and/or the like. These may be used alone or in combination with each other.

Accordingly, the transistor TR including the active pattern ACT, the gate electrode GE, the first electrode SD1, and the second electrode SD2 may be arranged on the substrate SUB.

The via insulating layer VIA may be arranged on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, and/or the like. These may be used alone or in combination with each other.

The pixel electrode PE may be arranged on the via insulating layer VIA. The pixel electrode PE may be connected to the second electrode SD2 (or the first electrode SD1) through a contact hole penetrating (e.g., passing through) the via insulating layer VIA. The pixel electrode PE may include a metal, an alloy, a conductive metal nitride, a conductive metal oxide, a transparent conductive material, and/or the like. These may be used alone or in combination with each other.

The pixel defining layer PDL may be arranged on the via insulating layer VIA, and may cover at least a portion of the pixel electrode PE. An opening exposing at least a portion of an upper surface of the pixel electrode PE may be defined in the pixel defining layer PDL. The pixel defining layer PDL may include an organic material or an inorganic material. For example, the pixel defining layer PDL may include an organic material such as an epoxy resin, a siloxane resin, and/or the like. For another example, the pixel defining layer PDL may include an organic material or an inorganic material including a light blocking material having a black color.

The light emitting layer EL may be arranged on the pixel electrode PE. The light emitting layer EL may be arranged on the pixel electrode PE exposed by the pixel defining layer PDL. The light emitting layer EL may include a material that may be to emit light of a set or predetermined color.

The common electrode CE may be arranged on the light emitting layer EL. The common electrode CE may include a metal, an alloy, a conductive metal nitride, a conductive metal oxide, a transparent conductive material, and/or the like. These may be used alone or in combination with each other.

Accordingly, the light emitting element LE including the pixel electrode PE, the light emitting layer EL, and the common electrode CE may be arranged on the substrate SUB. The light emitting element LE may be electrically connected to the transistor TR. The light emitting element LE may be to generate and/or emit light corresponding to a driving current provided from the transistor TR. The transistor TR and the light emitting element LE may correspond to each of the pixels PX, e.g., each of the pixels may include a transistor TR and a light emitting LE as described above.

The encapsulation layer TFE may be arranged on the common electrode CE. The encapsulation layer TFE may protect the light emitting element LE from external oxygen, moisture, and/or the like, or reduce the likelihood the light emitting element LE will be exposed to the aforementioned. The encapsulation layer TFE may include at least one inorganic layer and at least one organic layer. For example, the encapsulation layer TFE may have a structure in which inorganic layers and organic layers are alternately stacked.

The cover layer CIC may be arranged in the third area A3 on the display panel PN to cover the data driver DIC and the alignment mark AM. The cover layer CIC may include a first cover layer CIC1 and a second cover layer CIC2 arranged on the first cover layer CIC1. In one or more embodiments, the first cover layer CIC1 may cover the alignment mark AM, and the second cover layer CIC2 may not cover the alignment mark AM. The first cover layer CIC1 may extend in the first direction DR1 to cover the alignment mark AM. In a plan view, the first cover layer CIC1 may overlap the alignment mark AM, and the second cover layer CIC2 may not overlap the alignment mark AM.

In one or more embodiments, a third width W21 of the first cover layer CIC1 may be greater than a fourth width W22 of the second cover layer CIC2. Here, the third width W21 may be a length of the first cover layer CIC1 in the first direction DR1, and the fourth width W22 may be a length of the second cover layer CIC2 in the first direction DR1. The third width W21 may be substantially equal to the first width W1 of the display panel PN, and the fourth width W22 may be less than the first width W1 of the display panel PN.

In a plan view, third side surfaces S21 at opposite ends of the first cover layer CIC1, facing away from each other along the first direction DR1 may overlap (e.g., align with) the first side surfaces S1 of the display panel PN, respectively, and fourth side surfaces S22 at opposite ends of the second cover layer CIC2, facing away from each other along the first direction DR1 may not overlap (e.g., align with) the first side surfaces S1 of the display panel PN, respectively. In other words, the first cover layer CIC1 may have third side surfaces S21, one of the third side surfaces S21 is at an end (a first end) of the upper surface of the first cover layer CIC1 along the first direction DR1, and the other third side surface is at another end, opposite to the first end, of the upper surface of the first cover layer CIC1 along the first direction DR1. The length of the third side surfaces S21 may extend in the second direction DR2. The second cover layer CIC2 may have fourth side surfaces S22, and similar to the third side surfaces, the fourth side surfaces are at opposites end of the upper surface of the second cover layer CIC2 along the first direction DR1. The fourth side surfaces S22 may also extend in the second direction DR2. Each of the third side surfaces S21 may be aligned with a respective one of the first side surfaces S1. The fourth side surfaces S4 may not be aligned with the first side surfaces S1 or the third side surfaces S21.

The third side surfaces S21 may protrude further in the first direction DR1 and in a direction opposite to the first direction DR1 than the fourth side surfaces S22 protrude in the first direction DR1 and the direction opposite to the first direction DR1, respectively. For example, the second width W2 of the cover layer CIC may correspond to the third width W21 of the first cover layer CIC1, and the second side surfaces S2 of the cover layer CIC may correspond to (e.g., align with) the third side surfaces S21 of the first cover layer CIC1.

The first cover layer CIC1 may include a first transmission layer TL1 and a second transmission layer TL2 arranged on the first transmission layer TL1. The first transmission layer TL1 may couple the second transmission layer TL2 to the display panel PN, the bending protective layer BPL, or the circuit board CB. The first cover layer CIC1 may include an optically transparent material. For example, the first transmission layer TL1 may include a pressure sensitive adhesive, an optically clear adhesive, an optically clear resin, and/or the like, and the second transmission layer TL2 may include polyethylene terephthalate, acrylic, polyimide, and/or the like. The first cover layer CIC1 may improve impact resistance, protection functions, and/or the like of the cover layer CIC.

The first thickness TH1 of the cover layer CIC may be a sum of a third thickness TH11 of the first cover layer CIC1 and a fourth thickness TH12 of the second cover layer CIC2. Here, the third thickness TH11 may be a length of the first cover layer CIC1 in the third direction DR3, and the fourth thickness TH12 may be a length of the second cover layer CIC2 in the third direction DR3. In one or more embodiments, the third thickness TH11 of the first cover layer CIC1 may be adjusted to form an appropriate or suitable curvature in the second area A2. For example, thicknesses of each of the first and second transmission layers TL1 and TL2 may be adjusted.

For example, if (e.g., when) the second thickness TH2 of the bending protective layer BPL is relatively thick, the third thickness TH11 may also be relatively thick, and if (e.g., when) the second thickness TH2 is relatively thin, the third thickness TH11 may also be relatively thin. However, in the present disclosure, the third thickness TH11 is not limited, and the third thickness TH11 may be variously changed in consideration of the second thickness TH2, a material included in the first cover layer CIC1, physical properties (e.g., modulus) of the material, and/or the like.

The first cover layer CIC1 covering the alignment mark AM may be optically transparent. Accordingly, even if an image of the alignment mark AM covered by the first cover layer CIC1 is captured below the display device 10 after the display panel PN is bent, the alignment mark AM may be recognized. In addition, because the first cover layer CIC1 covers the alignment mark AM, rigidity of the area in which the alignment mark AM is defined may be supplemented. Accordingly, the recognition rate of the alignment mark AM may be improved.

The second cover layer CIC2 may include a first conductive layer CL1, a second conductive layer CL2 arranged on the first conductive layer CL1, and an organic layer OL arranged on the second conductive layer CL2. The first conductive layer CL1 may couple the second conductive layer CL2 to the first cover layer CIC1. The second cover layer CIC2 may include a conductive material. For example, the first conductive layer CL1 may include a conductive adhesive, and the second conductive layer CL2 may include a metal, an alloy, a conductive metal oxide, and/or the like. The organic layer OL may include an organic insulating material. For example, the organic layer OL may include polyethylene terephthalate, and/or the like. In one or more embodiments, the organic layer OL may include an organic material having a black color, and may serve as a light shield. The second cover layer CIC2 may shield static electricity. The second cover layer CIC2 may prevent or reduce the likelihood that the display panel PN, the circuit board CB, and/or the like may be damaged by external static electricity.

The display device 10 according to one or more embodiments of the present disclosure may include the display panel PN including the first area A1 in which the display area DA is defined (included), the second area A2 defined as a bending area, and the third area A3 in which the alignment mark AM is defined, the cover panel CP in contact with the first area A1 and the third area A3, and the cover layer CIC extending to cover the alignment mark AM on the third area A3. Because the area in which the alignment mark AM is defined may be supported by the cover layer CIC, even if a separate component is not arranged between the display panel PN and the cover panel CP, the recognition rate of the alignment mark AM may be improved after bending the display panel PN. Accordingly, the display device 10 may be thinned and process costs may be reduced.

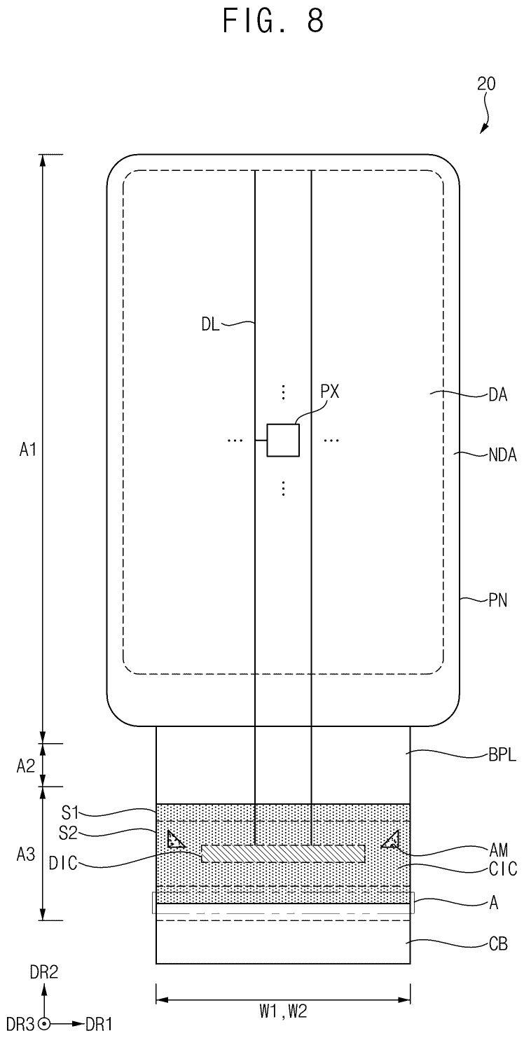

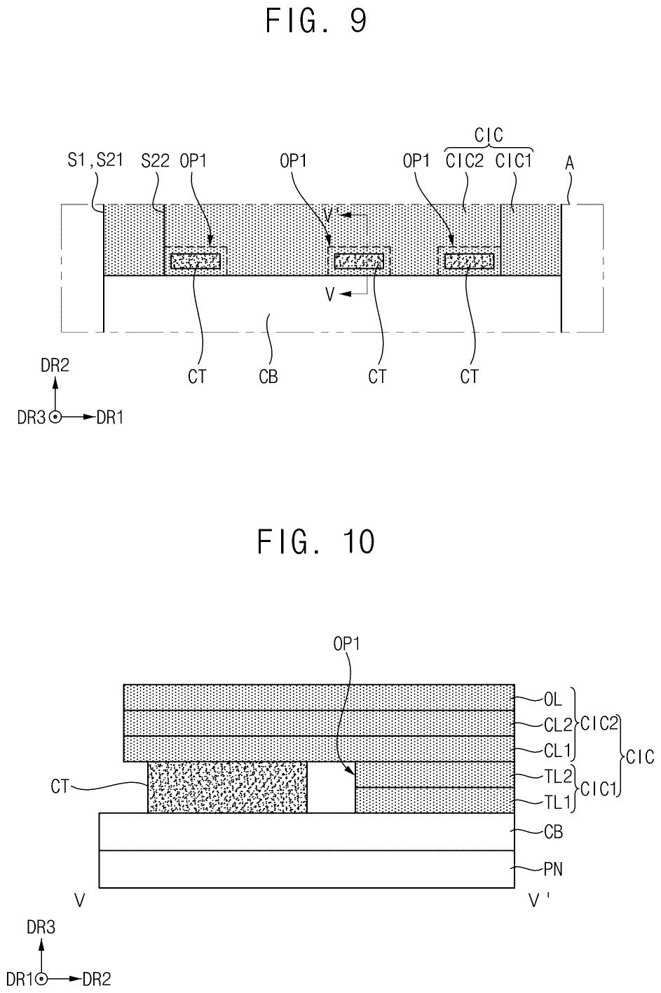

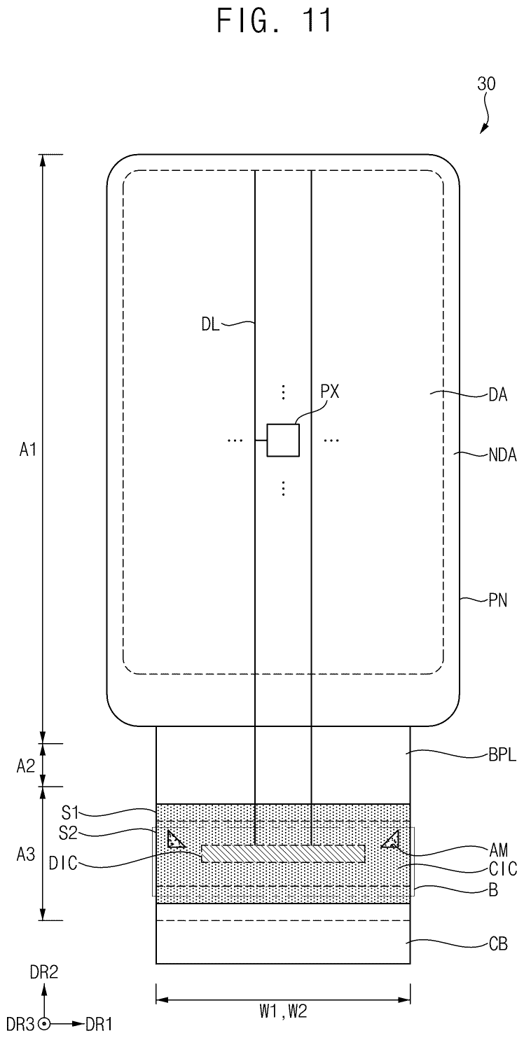

FIG. 8 is a plan view illustrating a display device according to one or more embodiments of the present disclosure. FIG. 9 is an enlarged plan view of area A of FIG. 8, according to one or more embodiments of the present disclosure. FIG. 10 is a cross-sectional view taken along the line V-V′ of FIG. 9, according to one or more embodiments of the present disclosure.

A display device 20 described with reference to FIGS. 8, 9, and 10 may be substantially the same as or similar to the display device 10 described with reference to FIGS. 1 to 7 except for the cover layer CIC. Hereinafter, redundant descriptions will not be provided or may be simplified.

For example, FIG. 8 may correspond to the plan view of FIG. 5, and FIGS. 9 and 10 may be views illustrating an area in which a display panel PN, a circuit board CB, and a cover layer CIC overlap in a plan view.

Referring to FIGS. 8, 9, and 10, the display device 20 may include the display panel PN, a bending protection layer BPL, the circuit board CB, and the cover layer CIC.

The display panel PN may include a display area DA and a non-display area NDA that may correspond to a display area that displays an image and a non-display area that does not display an image of the display device 20, respectively.

The display panel PN may include a first area A1, a second area A2, and a third area A3. The first area A1 may be an area in which the display area DA is defined, the second area A2 may be an area that is bent with respect to a bending axis, and the third area A3 may be an area that is arranged below the first area A1 after the second area A2 is bent. The display panel PN may include a data driver DIC and an alignment mark AM arranged in the third area A3.

The bending protection layer BPL may be arranged in the second area A2 on the display panel PN, and may be further arranged in a portion of the first area A1 and a portion of the third area A3 on the display panel PN. The bending protection layer BPL may be bent together with the second area A2.

The circuit board CB may be arranged in a portion of the third area A3 on the display panel PN. For example, the circuit board CB may be coupled with an end of the third area A3. The circuit board CB may be electrically connected to the display panel PN.

The circuit board CB may further include conductive patterns CT arranged in the third area A3 of the display panel PN. For example, the conductive patterns CT may be arranged to be spaced and/or apart (e.g., spaced apart or separated) from each other along a first direction DR1. The conductive patterns CT may include a metal, an alloy, a conductive metal nitride, a conductive metal oxide, a transparent conductive material, and/or the like. These may be used alone or in combination with each other.

The cover layer CIC may be arranged in the third area A3 on the display panel PN. The cover layer CIC may cover the data driver DIC and the alignment mark AM, and may further cover a portion of the bending protection layer BPL and a portion of the circuit board CB. In one or more embodiments, the conductive pattern CT may overlap the cover layer CIC in a plan view. The cover layer CIC may cover the conductive pattern CT.

In one or more embodiments, a first width W1 of the third area A3 of the display panel PN may be substantially equal to a second width W2 of the cover layer CIC. In a plan view, first side surfaces S1 at opposite ends of the third area A3 of the display panel PN, facing away from each other along the first direction DR1 and second side surfaces S2 at opposite ends of the cover layer CIC, facing away from each other along the first direction DR1 may overlap, respectively.

The cover layer CIC may include a first cover layer CIC1 and a second cover layer CIC2 arranged on the first cover layer CIC1. The first cover layer CIC1 may include a first transmission layer TL1 and a second transmission layer TL2 arranged on the first transmission layer TL1. The second cover layer CIC2 may include a first conductive layer CL1, a second conductive layer CL2 arranged on the first conductive layer CL1, and an organic layer OL arranged on the second conductive layer CL2.

In one or more embodiments, a width of the first cover layer CIC1 may be greater than a width of the second cover layer CIC2. The width of the first cover layer CIC1 may be substantially equal to the first width W1, and the width of the second cover layer CIC2 may be less than the first width W1. In a plan view, third side surfaces S21 at opposite ends of the first cover layer CIC1, facing away from each other along the first direction DR1 may overlap the first side surfaces S1, respectively, and fourth side surfaces S22 at opposite ends of the second cover layer CIC2, facing away from each other along the first direction DR1 may not overlap the first side surfaces S1, respectively. The third side surfaces S21 may protrude further in the first direction DR1 and in a direction opposite to the first direction DR1 than the fourth side surfaces S22 extend in the first direction DR1 and in the opposite direction to the first direction DR1, respectively. For example, the second side surfaces S2 of the cover layer CIC may correspond to the third side surfaces S21 of the first cover layer CIC1.

In one or more embodiments, the first cover layer CIC1 may define a first opening OP1. The first opening OP1 may penetrate the first cover layer CIC1 in a third direction DR3. The first opening OP1 may overlap the conductive patterns CT in a plan view. For example, the conductive patterns CT may be accommodated in the first opening OP1.

The conductive patterns CT may be connected to the second cover layer CIC2 through the first opening OP1. For example, the second cover layer CIC2 may cover upper surfaces of the conductive patterns CT. The second cover layer CIC2 may include a conductive material. The conductive patterns CT and the second cover layer CIC2 may shield static electricity or unnecessary current that may be generated when the display device 20 is driven.

Although FIG. 9 illustrates that the first opening OP1 overlaps the second cover layer CIC2 in a plan view, the present disclosure is not limited thereto. For example, the first opening OP1 may partially overlap the second cover layer CIC2.

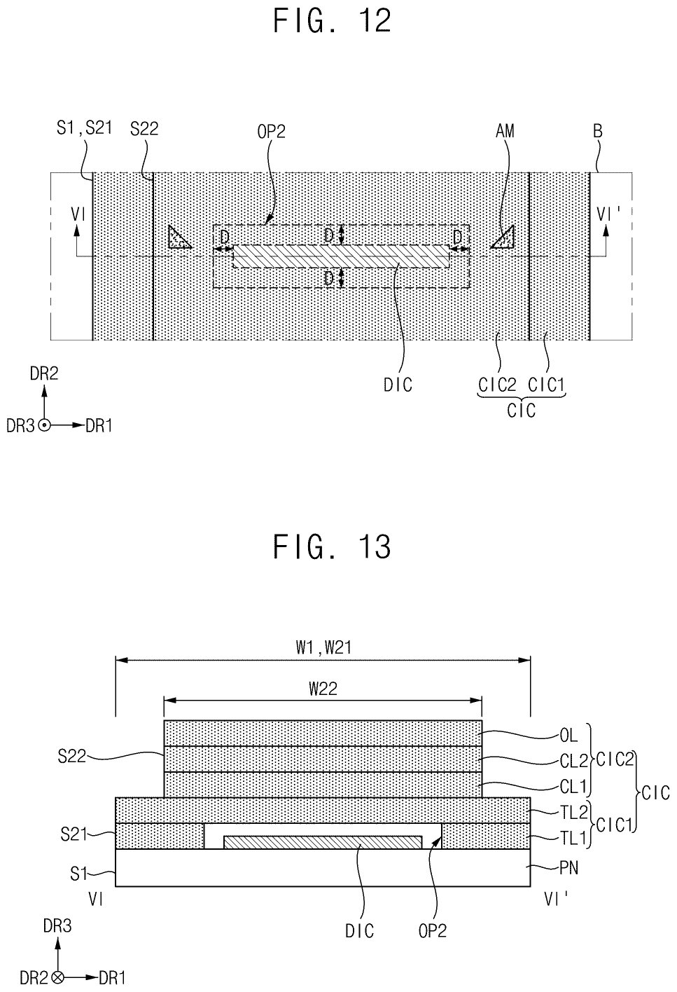

FIG. 11 is a plan view illustrating a display device according to one or more embodiments of the present disclosure. FIG. 12 is an enlarged plan view of area B of FIG. 11, according to one or more embodiments of the present disclosure. FIG. 13 is a cross-sectional view taken along the line VI-VI′ of FIG. 12, according to one or more embodiments of the present disclosure.

A display device 30 described with reference to FIGS. 11, 12, and 13 may be substantially the same as or similar to the display device 10 described with reference to FIGS. 1 to 7 except for the cover layer CIC. Hereinafter, redundant descriptions will not be provided or may be simplified.

For example, FIG. 11 may correspond to the plan view of FIG. 5, and FIGS. 12 and 13 may be views illustrating a third area A3.

Referring to FIGS. 11, 12, and 13, the display device 30 may include a display panel PN, a bending protection layer BPL, a circuit board CB, and a cover layer CIC.

The display panel PN may include and a display area DA and a non-display area NDA that may correspond to a display area that displays an image and a non-display area that does not display an image of the display device 30, respectively.

The display panel PN may include a first area A1, a second area A2, and the third area A3. The first area A1 may be an area in which the display area DA is defined, the second area A2 may be an area that is bent with respect to a bending axis, and the third area A3 may be an area that is arranged below the first area A1 after the second area A2 is bent. The display panel PN may include a data driver DIC and an alignment mark AM arranged in the third area A3.

The bending protection layer BPL may be arranged in the second area A2 on the display panel PN, and may be further arranged in a portion of the first area A1 and a portion of the third area A3 on the display panel PN. The bending protection layer BPL may be bent together with the second area A2.

The circuit board CB may be arranged in a portion of the third area A3 on the display panel PN. For example, the circuit board CB may be coupled with an end of the third area A3. The circuit board CB may be electrically connected to the display panel PN.

The cover layer CIC may be arranged in the third area A3 on the display panel PN. The cover layer CIC may cover the data driver DIC and the alignment mark AM, and may further cover a portion of the bending protection layer BPL and a portion of the circuit board CB.

In one or more embodiments, a first width W1 of the third area A3 of the display panel PN may be substantially equal to a second width W2 of the cover layer CIC. In a plan view, first side surfaces S1 at opposite ends of the third area A3 of the display panel PN, facing away from each other along a first direction DR1 and second side surfaces S2 at opposite ends of the cover layer CIC, facing away from each other along the first direction DR1 may overlap, respectively.

The cover layer CIC may include a first cover layer CIC1 and a second cover layer CIC2 arranged on the first cover layer CIC1. The first cover layer CIC1 may include a first transmission layer TL1 and a second transmission layer TL2 arranged on the first transmission layer TL1. The second cover layer CIC2 may include a first conductive layer CL1, a second conductive layer CL2 arranged on the first conductive layer CL1, and an organic layer OL arranged on the second conductive layer CL2.

In one or more embodiments, a third width W21 of the first cover layer CIC1 may be greater than a fourth width W22 of the second cover layer CIC2. The third width W21 may be substantially equal to the first width W1, and the fourth width W22 may be less than the first width W1. In a plan view, third side surfaces S21 at opposite ends of the first cover layer CIC1, facing away from each other along the first direction DR1 may overlap the first side surfaces S1, respectively, and fourth side surfaces S22 at opposite ends of the second cover layer CIC2, facing away from each other along the first direction DR1 may not overlap the first side surfaces S1, respectively. The third side surfaces S21 may protrude further in the first direction DR1 and a direction opposite to the first direction DR1 than the fourth side surfaces S22 may protrude in the first direction DR1 and the direction opposite to the first direction DR1, respectively. For example, the second width W2 of the cover layer CIC may correspond to the third width W21 of the first cover layer CIC1, and the second side surfaces S2 of the cover layer CIC may correspond to the third side surfaces S21 of the first cover layer CIC1.

In one or more embodiments, the first transmission layer TL1 may define a second opening OP2. The second opening OP2 may penetrate the first transmission layer TL1 in a third direction DR3. The second opening OP2 may overlap the data driver DIC in a plan view. For example, the data driver DIC may be accommodated in the second opening OP2.

A planar area of the second opening OP2 may be larger than a planar area of the data driver DIC. For example, an edge of the data driver DIC and an edge of the second opening OP2 may be spaced and/or apart (e.g., spaced apart or separated) from each other by a distance D. For example, the distance D may be about 300 μm or more, but the present disclosure is not limited thereto.

The second transmission layer TL2 and the second cover layer CIC2 may be arranged at an upper surface of the data driver DIC. Because the cover layer CIC defines the second opening OP2 in which the data driver DIC is arranged, a driving failure of the data driver DIC due to deformation of the first cover layer CIC1 may be prevented or reduced.

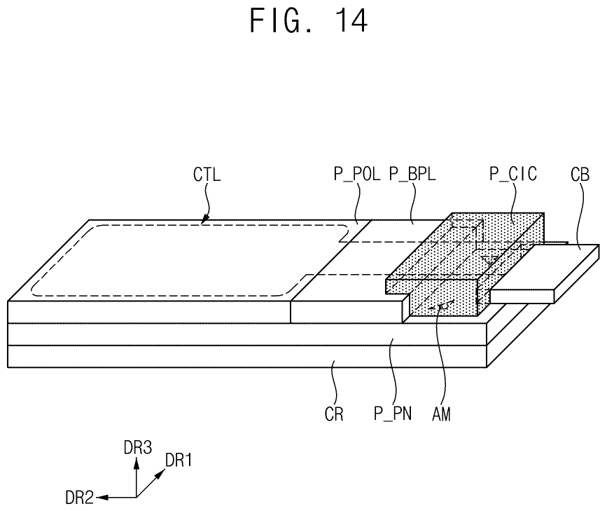

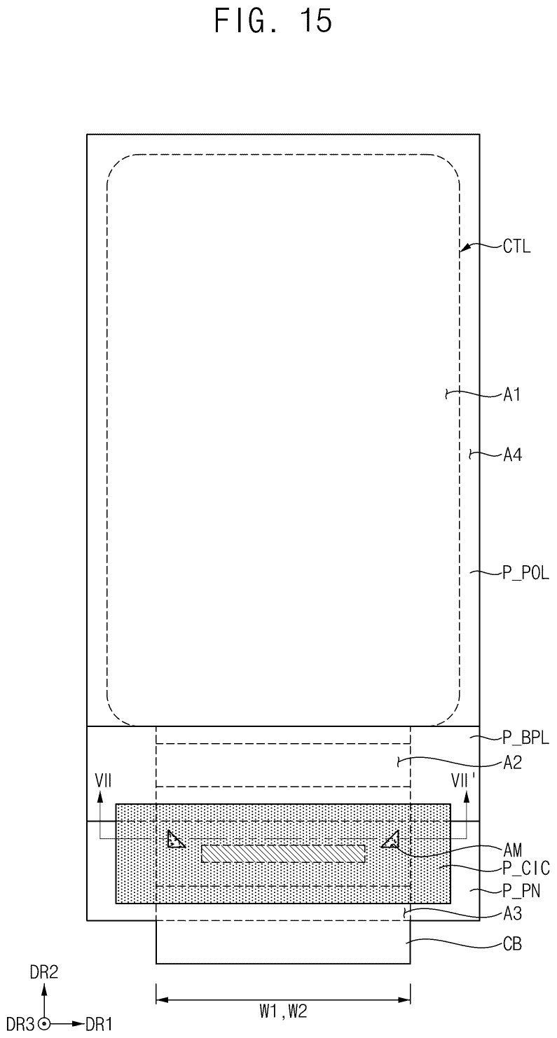

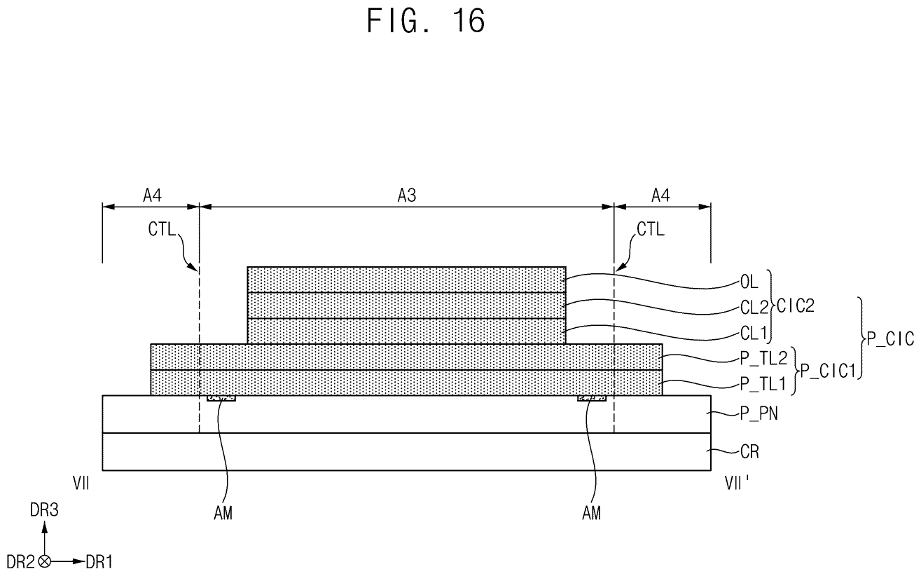

FIGS. 14, 15, and 16 are views illustrating a method of manufacturing a display device according to one or more embodiments of the present disclosure. For example, FIG. 14 may be a perspective view illustrating a method of manufacturing a display device, FIG. 15 may be a plan view of FIG. 14, and FIG. 16 may be a cross-sectional view taken along the line VII-VII′ of FIG. 15.

A method of manufacturing a display device described with reference to FIGS. 14, 15, and 16 may be a method of manufacturing the display device 10 described with reference to FIGS. 1 to 7, the display device 20 described with reference to FIGS. 8 to 10, or the display device 30 described with reference to FIGS. 11 to 13. Hereinafter, redundant descriptions will not be provided or simplified.

Referring to FIGS. 14, 15, and 16, a preliminary display panel P_PN may be provided (e.g., supplied) on a carrier film CR. The carrier film CR may be used for transporting the preliminary display panel P_PN. The carrier film CR may protect a lower portion of the preliminary display panel P_PN.

The preliminary display panel P_PN may include a first area A1, a second area A2, a third area A3, and a dummy area A4. The first, second, and third areas A1, A2, and A3 may be arranged in a direction opposite to a second direction DR2. The second area A2 may be arranged between the first area A1 and the third area A3.

The dummy area A4 may define the first, second, and third areas A1, A2, and A3. The dummy area A4 may be around (e.g., surround) the first, second, and third areas A1, A2, and A3 in a plan view. In addition, the dummy area A4 may define a cutting line CTL. A boundary of the dummy area A4 and each of the first, second, and third areas A1, A2, and A3 may be defined as the cutting line CTL.

The preliminary display panel P_PN may include a data driver DIC and an alignment mark AM arranged in the third area A3. For example, the alignment mark AM may be defined adjacent to side surfaces at opposite sides of the preliminary display panel P_PN in the third area A3, facing away from each other along the first direction DR1.

A preliminary polarizing layer P_POL and a preliminary bending protection layer P_BPL may be formed on the preliminary display panel P_PN. The preliminary polarizing layer P_POL may be formed in the first area A1 and a portion of the dummy area A4 adjacent to the first area A1 on the preliminary display panel P_PN. The preliminary bending protection layer P_BPL may be formed in the second area A2, and a portion of the first area A1, a portion of the third area A3, and a portion of the dummy area A4 respectively adjacent to the second area A2 on the preliminary display panel P_PN.

A circuit board CB may be provided on the preliminary display panel P_PN. The circuit board CB may be coupled to a portion of the third area A3 on the preliminary display panel P_PN.

A preliminary cover layer P_CIC may be further formed on the preliminary display panel P_PN. The preliminary cover layer P_CIC may be formed in the third area A3 and a portion of the dummy area A4 adjacent to the third area A3 on the preliminary display panel P_PN. The preliminary cover layer P_CIC may cover the data driver DIC and the alignment mark AM. The preliminary cover layer P_CIC may further cover a portion of the preliminary bending protection layer P_BPL and a portion of the circuit board CB.

For example, the circuit board CB, the preliminary cover layer P_CIC, the preliminary bending protection layer P_BPL, and the preliminary polarization layer P_POL may be arranged on the preliminary display panel P_PN along the second direction DR2.

The preliminary cover layer P_CIC may include a preliminary first cover layer P_CIC1 and a second cover layer CIC2 arranged on the preliminary first cover layer P_CIC1. The preliminary first cover layer P_CIC1 may include a preliminary first transmission layer P_TL1 and a preliminary second transmission layer P_TL2 arranged on the preliminary first transmission layer P_TL1. The preliminary first transmission layer P_TL1 may couple the preliminary second transmission layer P_TL2 to the preliminary display panel P_PN, the preliminary bending protection layer BPL, and/or the circuit board CB. The preliminary first cover layer P_CIC1 may include an optically transparent material. For example, the preliminary first transmission layer P_TL1 may include a pressure sensitive adhesive, an optically clear adhesive, an optically clear resin, and/or the like, and the preliminary second transmission layer P_TL2 may include polyethylene terephthalate, acryl, polyimide, and/or the like.

In one or more embodiments, the preliminary first cover layer P_CIC1 may cover the alignment mark AM, and the second cover layer CIC2 may not cover the alignment mark AM. In a plan view, the first cover layer CIC1 may overlap the alignment mark AM, and the second cover layer CIC2 may not overlap the alignment mark AM.

In addition, the preliminary first cover layer P_CIC1 may be formed in the third area A3 and a portion of the dummy area A4 adjacent to the third area A3 on the preliminary display panel P_PN, and the second cover layer CIC2 may be formed in the third area A3 on the preliminary display panel P_PN. In a plan view, the preliminary first cover layer P_CIC1 may overlap the dummy area A4, and the second cover layer CIC2 may not overlap the dummy area A4. For example, the preliminary first cover layer P_CIC1 may extend in the first direction DR1 to cover the alignment mark AM and to overlap the dummy area A4 in a plan view, and the cutting line CTL may be defined in the preliminary first cover layer P_CIC1.

Thereafter, the preliminary polarizing layer P_POL, the preliminary bending protection layer P_BPL, the preliminary cover layer P_CIC, and the preliminary display panel P_PN may be cut along the dummy area A4 (e.g., along a boundary defining the dummy area A4). For example, the preliminary polarizing layer P_POL, the preliminary bending protection layer P_BPL, the preliminary cover layer P_CIC, and the preliminary display panel P_PN may be cut along the cutting line CTL, and the dummy area A4 of the preliminary display panel P_PN and portions of the preliminary polarizing layer P_POL, the preliminary bending protection layer P_BPL, and the preliminary cover layer P_CIC, which overlap the dummy area A4 in a plan view, may be removed.

Accordingly, referring to, for example, FIGS. 1, 2, 5, and 6, a display panel PN including the first, second, and third areas A1, A2, and A3 may be formed, and a polarizing layer POL, a bending protection layer BPL, the circuit board CB, and a cover layer CIC including a first cover layer CIC1 and the second cover layer CIC2 may be formed on the display panel PN.

The polarizing layer POL may be formed in the first area A1 on the display panel PN, and the bending protection layer BPL may be formed in the second area A2, a portion of the first area A1, and a portion of the third area A3 on the display panel PN. The cover layer CIC may be formed in the third area A3 on the display panel PN, and may be formed to cover the alignment mark AM.

Thereafter, a window WM may be coupled to the polarizing layer POL, and a cover panel CP may be coupled to a lower portion of the display panel PN. The second area A2 of the display panel PN may be bent, and the third area A3 may be arranged below the first area A1 to face the first area A1 in a third direction DR3. Accordingly, a display device in which the first area A1 and the third area A3 of the display panel PN are in direct contact with upper and lower surfaces of the cover panel CP, respectively, may be manufactured.

The display devices 10, 20, and 30 according to one or more embodiments of the present disclosure may be applied to various electronic devices. An electronic device according to one or more embodiments of the present disclosure may include the display device 10, the display device 20, or the display device 30 described above, and may further include a module or device having additional functions in addition to the display device 10, the display device 20, or the display device 30.

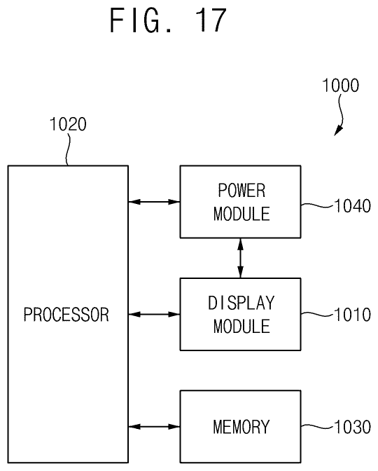

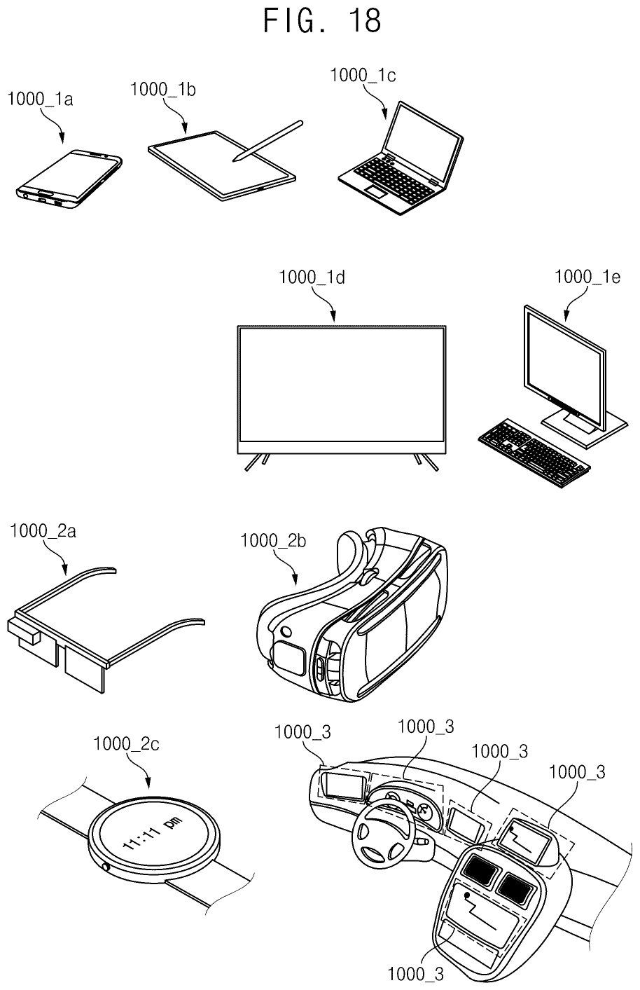

FIG. 17 is a block diagram illustrating an electronic device according to one or more embodiments of the present disclosure.

Referring to FIG. 17, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to one or more embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

FIG. 18 is a schematic view illustrating electronic devices according to one or more embodiments of the present disclosure

Referring to FIG. 18, various electronic devices to which the display device according to one or more embodiments of the present disclosure is applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to one or more suitable display devices. For example, the present disclosure is applicable to one or more suitable display devices such as display devices for vehicles, ships and/or aircraft, portable communication devices, display devices for exhibition or information transmission, medical display devices, and/or the like. In one or more embodiments, the display devices discussed herein may be included in electronic devices such as portable communication devices, such as mobile phones, medical display devices, vehicles, ships and/or aircraft.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value. Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus or any other relevant devices, manufacturing apparatus to manufacture the display device, or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising a first area, a second area adjacent to the first area and bent with respect to a bending axis extending in one direction, and a third area adjacent to the second area and comprising an alignment mark;
a cover layer below the third area of the display panel and covering the alignment mark; and
a cover panel between the first area and the third area of the display panel and in contact with the display panel.

2. The display device of claim 1, wherein a first width of the third area of the display panel in the one direction is equal to a second width of the cover layer in the one direction.

3. The display device of claim 2, wherein, in a plan view, first side surfaces at opposite ends of the third area of the display panel in the one direction overlap second side surfaces at opposite ends of the cover layer in the one direction, respectively.

4. The display device of claim 1, wherein the cover panel comprises:
a first surface in contact with the first area of the display panel; and
a second surface in contact with the third area of the display panel.

5. The display device of claim 1, wherein the third area of the display panel is below the first area of the display panel.

6. The display device of claim 3, wherein the cover layer comprises:
a first cover layer comprising an optically transparent material; and
a second cover layer on the first cover layer and comprising a conductive material.

7. The display device of claim 6, wherein
the first cover layer overlaps the alignment mark in the plan view, and
the second cover layer does not overlap the alignment mark in the plan view.

8. The display device of claim 6, wherein a third width of the first cover layer in the one direction is greater than a fourth width of the second cover layer in the one direction.

9. The display device of claim 8, wherein the third width of the first cover layer is equal to the first width of the third area of the display panel.

10. The display device of claim 6, wherein, in the plan view, third side surfaces at opposite ends of the first cover layer in the one direction do not overlap fourth side surfaces at opposite ends of the second cover layer in the one direction, respectively.

11. The display device of claim 10, wherein, in the plan view, the third side surfaces of the first cover layer overlap the first side surfaces of the display panel, respectively.

12. The display device of claim 6, further comprising:
a circuit board coupled to the third area of the display panel,
wherein the cover layer covers at least a portion of the circuit board.

13. The display device of claim 12, wherein
the circuit board comprises a conductive pattern overlapping the cover layer in the plan view, and
the first cover layer defines an opening overlapping the conductive pattern in the plan view.

14. The display device of claim 6, wherein
the display panel comprises a data driver in the third area, and
the cover layer covers the data driver.

15. The display device of claim 14, wherein
the first cover layer comprises a first transmission layer and a second transmission layer on the first transmission layer, and
the first transmission layer defines an opening overlapping the data driver in the plan view.

16. A method comprising:
supplying a preliminary display panel comprising a first area, a second area adjacent to the first area and being bendable, a third area adjacent to the second area and comprising an alignment mark, and a dummy area defining the first area, the second area, and the third area;
forming a preliminary cover layer covering the alignment mark in the third area and the dummy area on the preliminary display panel;
cutting the preliminary display panel and the preliminary cover layer along a boundary defining the dummy area to form a display panel comprising the first area, the second area, and the third area and a cover layer covering the alignment mark; and
coupling a cover panel to a lower portion of the display panel,
wherein the method is for manufacturing a display device.

17. The method of claim 16, wherein a first width of the third area of the display panel in one direction is equal to a second width of the cover layer in the one direction.

18. The method of claim 17, wherein, in a plan view,
first side surfaces at opposite ends of the third area of the display panel in the one direction overlap second side surfaces at opposite ends of the cover layer in the one direction, respectively.

19. The method of claim 16, further comprising:
bending the second area of the display panel with respect to a bending axis extending in one direction to position the third area of the display panel below the first area of the display panel.

20. The method of claim 19, wherein
a first surface of the cover panel is in contact with the first area of the display panel, and
a second surface of the cover panel is in contact with the third area of the display panel.

21. The method of claim 18, wherein the forming of the preliminary cover layer comprises:
forming a first cover layer overlapping the alignment mark in the plan view; and
forming a second cover layer on the first cover layer, the second cover layer not overlapping the alignment mark in the plan view.

22. The method of claim 21, wherein, after the cutting the preliminary display panel and the preliminary cover layer, a third width of the first cover layer in the one direction is equal to the first width of the third area of the display panel.

23. The method of claim 21, wherein, after the cutting the preliminary display panel and the preliminary cover layer, in the plan view, third side surfaces at opposite ends of the first cover layer in the one direction overlap the first side surfaces of the display panel, respectively.

24. The method of claim 16, further comprising:
coupling the third area and a circuit board,
wherein the circuit board comprises a conductive pattern overlapping the cover layer in a plan view, and the cover layer defines an opening overlapping the conductive pattern in the plan view.

25. The method of claim 16, wherein
the display panel comprises a data driver in the third area,
the cover layer covers the data driver, and
the cover layer defines an opening overlapping the data driver in a plan view.

26. An electronic device comprising:
a display device comprising:
a display panel comprising a first area, a second area adjacent to the first area and bent with respect to a bending axis extending in one direction, and a third area adjacent to the second area and comprising an alignment mark;
a cover layer below the third area of the display panel and covering the alignment mark; and
a cover panel between the first area and the third area of the display panel and in contact with the display panel.

27. The electronic device of claim 26, wherein the electronic device is a portable communication device, a medical display device, a vehicle, a ship or an aircraft.
